(19) United States
(12) Patent Application Publication
(10) Pub. No.: US 2016/0035727 A1
(43) Pub. Date: Feb. 4, 2016

(54) CMOS STRUCTURE WITH BENEFICIAL NMOS AND PMOS BAND OFFSETS

(71) Applicant: GLOBALFOUNDRIES Inc., Grand Cayman (KY)

(72) Inventor: David P. Brunco, Latham, NY (US)

(21) Appl. No.: 14/446,695

(22) Filed: Jul. 30, 2014

(51) Int. Cl. H01L 27/092; H01L 29/161; H01L 21/8238; H01L 29/78; H01L 21/02; H01L 29/06; H01L 29/36

(52) U.S. Cl. CPC H01L 27/0924; H01L 29/0653; H01L 29/161; H01L 29/36; H01L 27/0922; H01L 29/7848; H01L 21/02532; H01L 21/823821; H01L 21/823878; H01L 21/823814

(57) ABSTRACT

A CMOS structure with beneficial nMOS and pMOS band offsets is disclosed. A first silicon germanium layer is formed on a semiconductor substrate. A second silicon germanium layer is formed on the first silicon germanium layer. The second silicon germanium layer has a higher germanium percentage than the first silicon germanium layer. Furthermore, the germanium concentration of the two layers is selected such that there is a beneficial band offset for both N-type field effect transistors and P-type field effect transistors in a CMOS structure.

### FIELD OF THE INVENTION

The present invention relates generally to semiconductor fabrication, and more particularly, to semiconductor structures with beneficial NMOS and PMOS band offsets.

### BACKGROUND

A compressive stress or tensile stress can be applied to some types of transistors to increase their performance. For standard orientation wafers, the performance of a p-type field effect transistor (“PFET”) improves when a longitudinal (in the direction of current flow) compressive stress is applied to the channel region. On the other hand, the performance of an n-type field effect transistor (“NFET”) improves when a longitudinal tensile stress is applied to the channel region.

### SUMMARY

For heterostructures comprising different channel materials on an underlying structure, it is favorable to have a quantum barrier between the channel material and underlying structure to help confine carriers to the channel and thus reduce off-state leakage. When NFET devices and PFET devices are used together in a complementary metal oxide semiconductor (CMOS) structure, it is desirable to apply the appropriate type of stress for each device and to achieve the appropriate quantum barrier offset.

Embodiments of the present invention provide an improved CMOS structure. A first silicon germanium layer is formed on a semiconductor substrate. A second silicon germanium layer is formed on the first silicon germanium layer. The second silicon germanium layer has a higher germanium percentage than the first silicon germanium layer. Furthermore, the germanium concentration of the two layers is selected such that there is a beneficial band offset for both N-type field effect transistors and P-type field effect transistors in a CMOS structure.

In a first aspect, embodiments of the present invention provide a semiconductor structure comprising: a semiconductor substrate; a first silicon germanium layer disposed on the semiconductor substrate; a second silicon germanium layer disposed on the first silicon germanium layer; and a plurality of shallow trench isolation regions formed in the second silicon germanium layer and partially into the first silicon germanium layer; wherein the first silicon germanium layer has a first germanium concentration, and wherein the second silicon germanium layer has a second germanium concentration, and wherein the second germanium concentration is greater than the first germanium concentration.

In a second aspect, embodiments of the present invention provide a semiconductor structure comprising: a semiconductor substrate; a first silicon germanium layer disposed on the semiconductor substrate; a second silicon germanium layer disposed on the first silicon germanium layer; and a plurality of shallow trench isolation regions formed in the second silicon germanium layer and partially into the first silicon germanium layer; wherein the first silicon germanium layer has a first germanium concentration, and wherein the second silicon germanium layer has a second germanium concentration, and wherein the second germanium concentration is greater than the first germanium concentration; and wherein a conduction band offset between the second silicon germanium layer and the first silicon germanium layer ranges from about −0.05 eV to about −0.15 eV, and wherein a valence band offset between the second silicon germanium layer and the first silicon germanium layer ranges from about 0.05 eV to about 0.4 eV.

In a third aspect, embodiments of the present invention provide a method of forming a semiconductor structure, comprising: forming a first silicon germanium layer on a semiconductor substrate, the first silicon germanium layer having a first germanium concentration; forming a p-doped region in the first silicon germanium layer; forming an n-doped region in the first silicon germanium layer; and forming a second silicon germanium layer on the first silicon germanium layer, the second silicon germanium layer having a second germanium concentration that is greater than the first germanium concentration.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a semiconductor structure in accordance with embodiments of the present invention.

FIG. 2 shows a semiconductor structure comprising CMOS transistors in accordance with embodiments of the present invention.

FIG. 3 is a chart showing beneficial conduction band offset ranges.

FIG. 4 is a chart showing beneficial valence band offset ranges.

FIG. 5 is a chart showing a common beneficial band offset region.

FIG. 6 is a side view of a semiconductor structure in accordance with embodiments of the present invention.

FIG. 7 is a side view of a semiconductor structure after a subsequent process step of fin recess.

FIG. 8 is a side view of a semiconductor structure after a subsequent process step of depositing a stressor material.

FIG. 9 is a top-down view of a semiconductor structure in accordance with embodiments of the present invention.

FIG. 10 is a flowchart showing process steps for embodiments of the present invention.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Furthermore, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art.

The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” “some embodiments,” or similar language means that a particular feature, structure, or characteristic described in connection with the embodiment is included in at least one embodiment of the present invention. Thus, appearances of the phrases “in one embodiment,” “in an embodiment,” “in embodiments,” “in some embodiments,” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

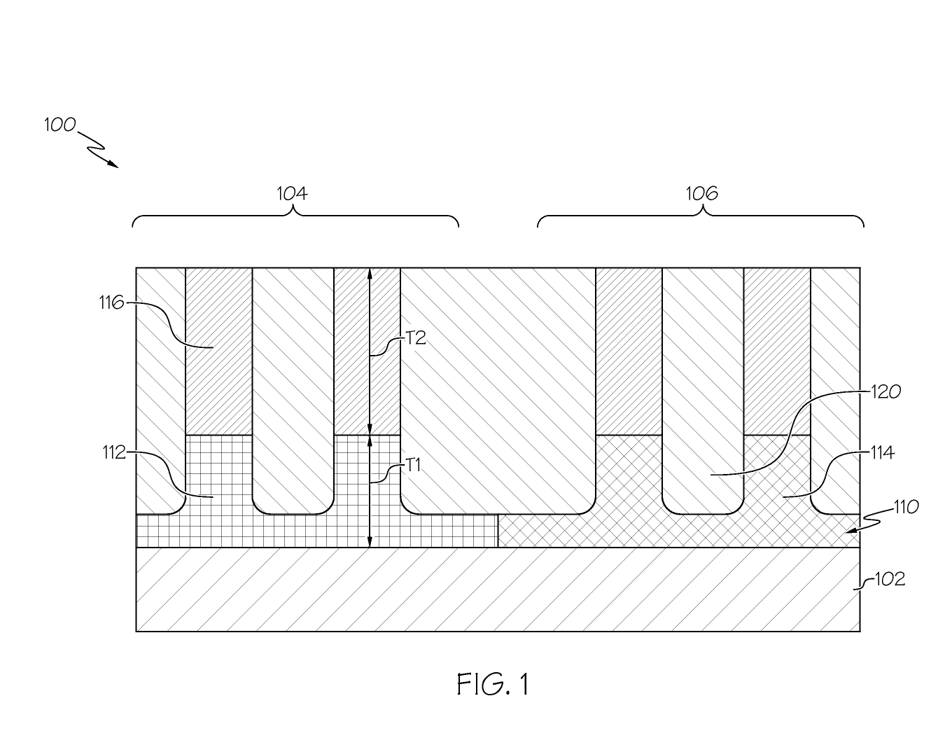

FIG. 1 shows a semiconductor structure 100 in accordance with embodiments of the present invention. Semiconductor structure 100 may comprise a bulk semiconductor substrate 102, which, in some embodiments, may be a bulk silicon substrate, such as a silicon wafer. In alternate embodiments, substrate 102 may be any other suitable material. A first silicon germanium (SiGe) layer 110 that is substantially relaxed in stress may be disposed on the semiconductor substrate 102, and a second silicon germanium layer 116 may be disposed on the first silicon germanium layer 110. In embodiments, the thickness T1 of the first silicon germanium layer ranges from about 100 nanometers to about 2000 nanometers. In embodiments, the thickness T2 of the second silicon germanium layer ranges from about 10 nanometers to about 90 nanometers.

The first silicon germanium layer 110 has a first germanium concentration, and the second silicon germanium layer 116 has a second germanium concentration that is greater than the first germanium concentration. This results in compressive as-formed stress in the second silicon germanium layer for growth that is epitaxial and substantially defect-free. In some embodiments, the first germanium concentration ranges from about 70 percent to about 95 percent, and the second germanium concentration ranges from about 80 percent to about 100 percent. In some embodiments, the first germanium concentration ranges from about 60 percent to about 70 percent, and the second germanium concentration ranges from about 85 percent to about 100 percent. In some embodiments, the first germanium concentration ranges from about 40 percent to about 60 percent, and the second germanium concentration ranges from about 90 percent to about 100 percent. In some embodiments, the first germanium concentration ranges from about 40 percent to about 60 percent, and the second germanium concentration ranges from about 90 percent to about 95 percent. In some embodiments, the first germanium concentration ranges from about 60 percent to about 70 percent, and the second germanium concentration ranges from about 75 percent to about 90 percent. In some embodiments, the first germanium concentration ranges from about 80 percent to about 85 percent, and the second germanium concentration ranges from about 90 percent to about 95 percent.

The semiconductor structure 100 may comprise doped regions. The first silicon germanium layer 110 may comprise an N-doped region 112 (an N-well). In some embodiments, the dopant may be at least one of arsenic, phosphorus, antimony, or any other suitable material. The first silicon germanium layer 110 may comprise a P-doped region 114. In some embodiments, the dopant may be at least one of boron, gallium, and indium. The doping in the well regions serves to contain charge carriers to the second silicon germanium layer 116, thus reducing sub-channel leakage current when the FET is in the off-state.

The semiconductor structure 100 may comprise field effect transistors and shallow trench isolation (STI) regions. In some embodiments, a P-type field effect transistor 104 and an N-type field effect transistor 106 may be formed adjacent to one another on the second silicon germanium layer 116. In some embodiments, the P-type field effect transistor (pFET) 104 is a fin-type field effect transistor, and the n-type field effect transistor (nFET) 106 is a fin-type field effect transistor. A plurality of STI regions 120 may also be formed in the second silicon germanium layer 116. In some embodiments, the STI regions 120 may comprise silicon oxide or another suitable material.

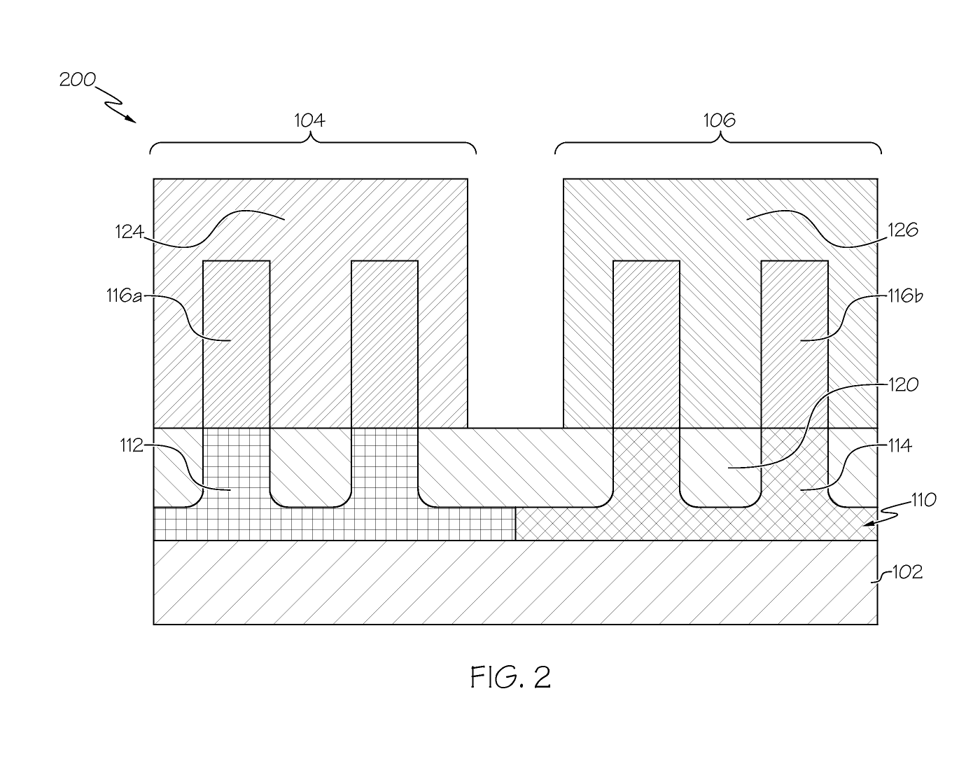

FIG. 2 shows a semiconductor structure 200 comprising CMOS transistors in accordance with embodiments of the present invention. The plurality of STI regions 120 have been partially recessed, and gate 124 has been formed over the fins 116a of the pFET 104, and gate 126 has been formed over the fins 116b of the nFET 106. The fins 116a and 116b are formed predominantly from the second silicon germanium layer.

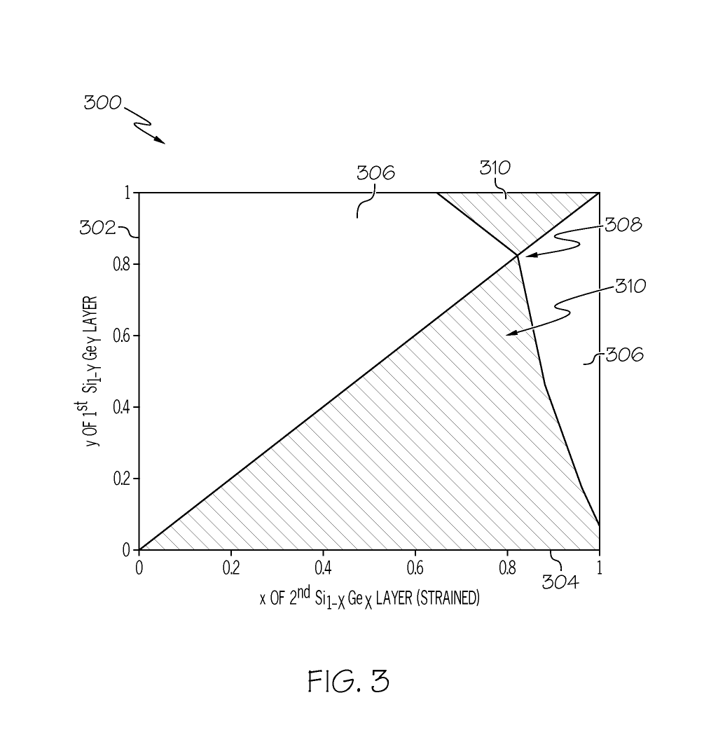

FIG. 3 is a chart 300 showing conduction band offset values in electron Volts (eV) for an unstrained first SiGe layer and a uniaxially strained second SiGe layer, as is appropriate for commensurate growth on the first SiGe layer and a FinFET geometry. The X axis 302 represents the atomic fraction of Ge in the second silicon germanium layer, and the Y axis 304 represents the atomic fraction of Ge in the first silicon germanium layer. NFETs benefit from a negative conduction band offset value, which is represented by the unshaded region 306. Negative values for the conduction band offset provide quantum well isolation of electrons in the second SiGe layer, which is beneficial to nFET operation. For example, the point shown at 308 on the chart 300 represents a condition of an X value of 0.9 and a Y value of 0.8, which means that the first silicon germanium layer is Si0.2Ge0.8 and the second silicon germanium layer is Si0.1 Ge0.9. This point 308 has a conduction band offset of −0.05 eV, as can be seen from the contour line. The shaded regions 310 have positive conduction band offsets and should be avoided.

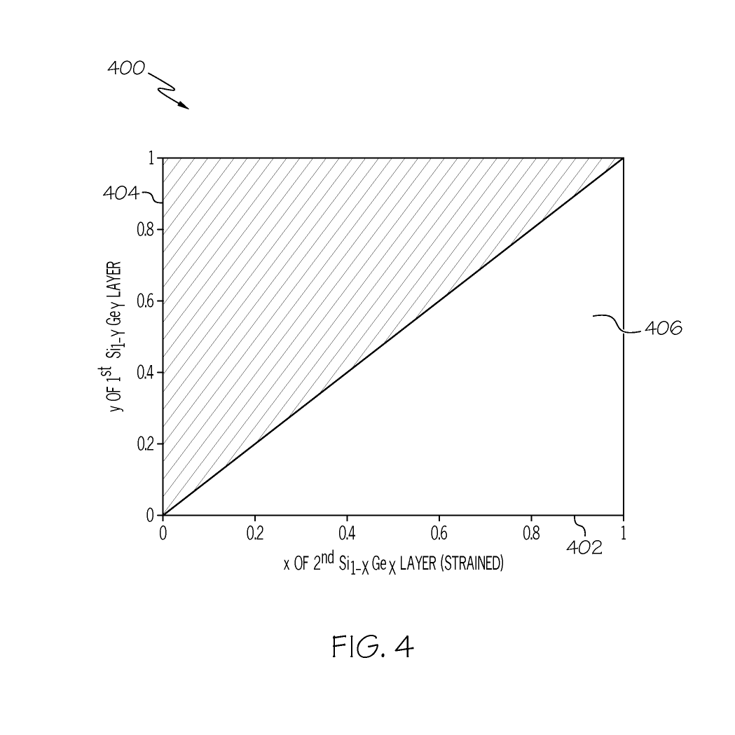

FIG. 4 is a chart 400 showing valence band offset values in electron Volts (eV) for an unstrained first SiGe layer and a uniaxially strained second SiGe layer, as is appropriate for commensurate growth on the first SiGe layer and a FinFET geometry. The X axis 402 represents the atomic fraction of Ge in the second silicon germanium layer, and the Y axis 404 represents the atomic fraction of Ge in the first silicon germanium layer. The unshaded region 406 represents an area of valence band offset that is effective for pFETs. As shown, P-type field effect transistors typically benefit from a positive valence band offset value.

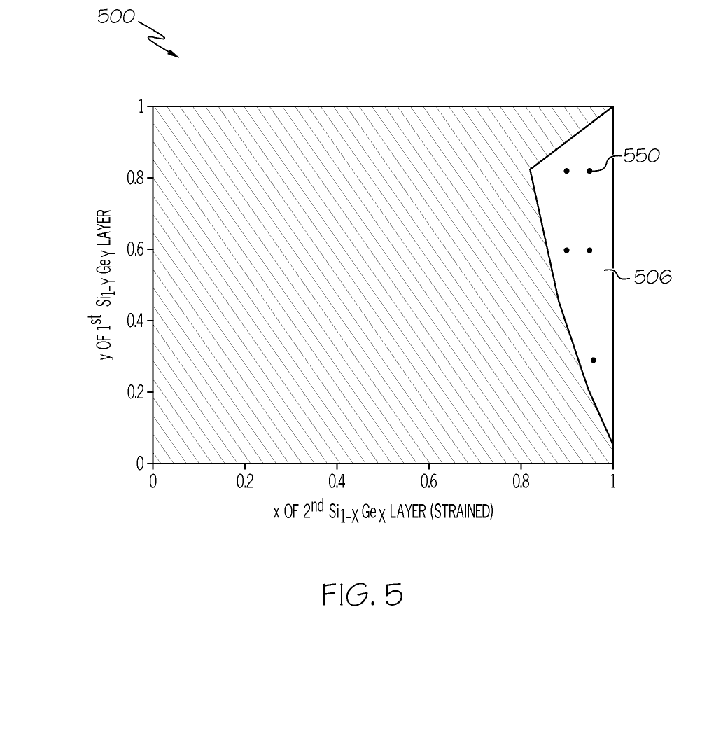

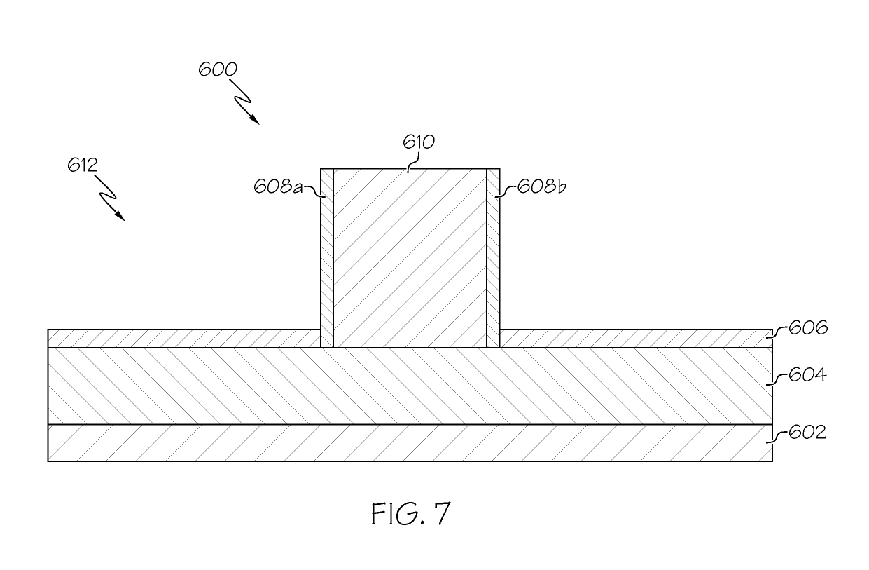

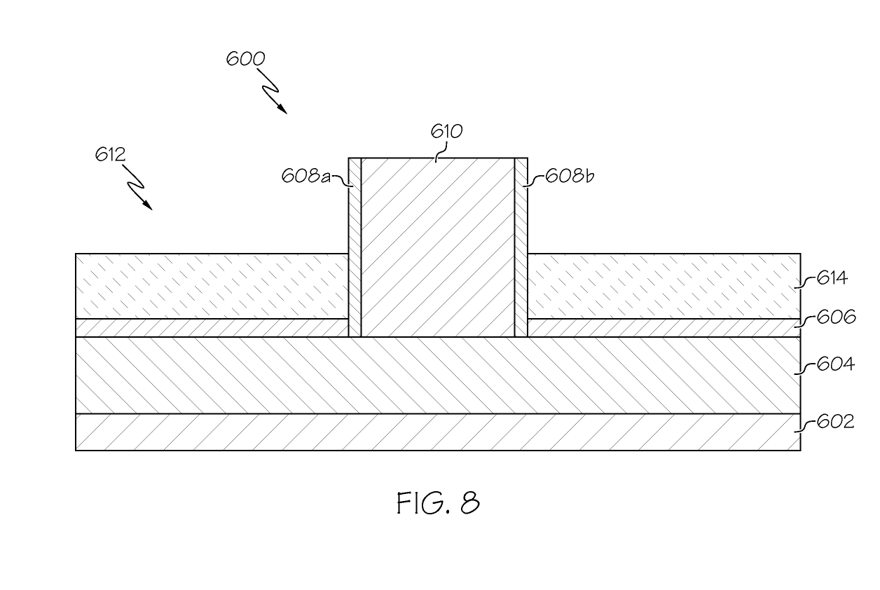

FIG. 5 is a chart showing a common band offset value in electron Volts (eV) for an unstrained first SiGe layer and a uniaxially strained second SiGe layer, as is appropriate for commensurate growth on the first SiGe layer and a FinFET geometry. The common band offset is the region of chart 500 that achieves both a positive valence band offset and a negative conduction band offset. The unshaded region 506 on chart 500 of FIG. 5 represents the intersection of the unshaded regions 306 and 406 of chart 300 (FIG. 3) and chart 400 (FIG. 4), respectively. This combination of layers indicated by the shaded region 506 has a beneficial stress impact for pFETs, but a slightly adverse stress impact for nFETs. This is mitigated by the use of the fin recess region and subsequent growth of a source/drain stressor for nFETs (see 612 of FIG. 7 and 614 of FIG. 8). Examination of conduction and valence band offsets for strained high-Ge SiGe (second SiGe layer 116 of FIGS. 1 and 2) on a SiGe strain relaxed buffer (first SiGe layer 110 of FIGS. 1 and 2) showed that over a small composition range, favorable valence and conduction band offsets of up to ˜150 meV are possible. These offsets are advantageous for both nMOS and pMOS. Some examples of possible combinations are represented by points 550. For a first silicon germanium layer with a Ge atomic fraction y and second silicon germanium layer with a Ge atomic fraction x, the common beneficial region for some embodiments of this invention is approximately bounded by 0.8≦x≦1, y>x, and y≧−3.5x+3.6.

A semiconductor structure in embodiments of the present invention comprises nFETs with a negative conduction band offset between the second silicon germanium layer and first silicon germanium layer and comprises pFETs with a positive valence band offset between the second silicon germanium layer and first silicon germanium layer. Furthermore, for embodiments of the present invention, the transistor channels, which define the region of charge carrier flow between the source and drain, are substantially contained within the second silicon germanium layer and substantially do not cross into the first silicon germanium layer. As a result, there is a quantum barrier helping to confine mobile electrons to the channel of the nFET and helping to confine mobile holes to the channel of the pFET. This provides a reduction of leakage in the off-state by suppressing sub-channel conduction. In some embodiments, the conduction band offset between the second silicon germanium layer and first silicon germanium layer ranges from about −0.05 electron volts (eV) to about −0.15 eV. In some embodiments, the valence band offset between the second silicon germanium layer and first silicon germanium layer ranges from about 0.05 eV to about 0.4 eV.

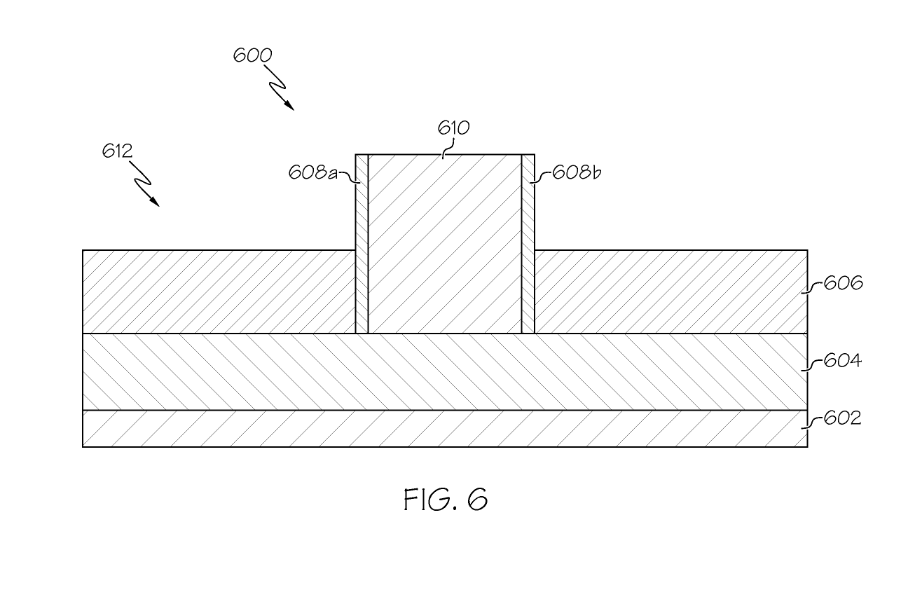

FIG. 6 is a side view of a semiconductor structure 600 in accordance with embodiments of the present invention. The semiconductor structure 600 includes a substrate, which may be a bulk substrate 602, such as a silicon wafer. A first silicon germanium (SiGe) layer 604 is disposed on the bulk substrate 602. A second SiGe layer 606 is disposed over the first SiGe layer 604. The first silicon germanium layer 604 has a first germanium concentration, and the second silicon germanium layer 606 has a second germanium concentration that is greater than the first germanium concentration. A gate 610 is disposed on the semiconductor structure. Spacers 608a and 608b are formed adjacent the gate. In embodiments, the gate 610 is a metal gate, and may be formed by a replacement metal gate (RMG) process. In embodiments, the metal gate may comprise one or more of tantalum, tungsten, aluminum, and/or another suitable material. In embodiments, the spacers 608a and 608b are comprised of silicon nitride.

FIG. 7 is a side view of a semiconductor structure 600 after a subsequent process step of fin recess in the source and drain regions. Semiconductor structure 600 is shown after the second SiGe layer 606 is recessed. In some embodiments, the recessing is achieved using a selective reactive ion etch (RIE) process. The recessed region is shown generally at reference number 612. The recess is substantially anisotropic. However, some embodiments may include some lateral etching. This recess results in partial relaxation of the stress in the fin under the gate 610 and spacers 608a and 608b, as it provides free volume to the “left” and “right” of the fin for stress relief. For the nMOS device, where the higher Ge composition of the second layer results in compressive, as-grown stress in the second silicon germanium layer, this relaxation provides mobility benefit, as it reduces undesirable compressive stress. For the pMOS device, this relaxation is undesirable, but some recess may be necessary for manufacturing concerns. In some embodiments, the recess 612 for the nMOS regions is deeper than that for the pMOS regions. In some embodiments, the recess 612 for nMOS regions is at least 5 nanometers deeper than a corresponding recess for a pMOS region. This can be achieved using patterning and etch techniques standard in the industry.

FIG. 8 is a side view of a semiconductor structure 600 after a subsequent process step of depositing a stressor material 614 in the source and drain regions. Note that the recess 612 and stressor material 614 may be different for nMOS devices and pMOS devices. In embodiments, source and drain regions for the pMOS contains compressively-strained silicon germanium with a germanium concentration higher than that of the second silicon germanium layer. Additionally, source and drain regions for the nMOS may contain tensile-strained silicon or silicon germanium with a Ge concentration at least 10% lower than that of the first silicon germanium layer. Thus, some embodiments include a compressively-strained silicon germanium layer on a subset of the plurality of fins that correspond to a PFET device, and also include a tensile-strained silicon germanium layer on a subset of the plurality of fins that correspond to an NFET device.

Semiconductor structure 600 is shown after a stressor material 614 is formed (using, e.g., epitaxial growth) in the recessed region 612. In some embodiments, the stressor material 614 for the nMOS regions may comprise epitaxial silicon or silicon germanium having a lower germanium concentration than the first silicon germanium layer 604. This stressor material induces a favorable tensile stress into the nFinFET channel. Hence, this embodiment allows for beneficial band offset values for nMOS devices, while providing a favorable tensile stress state. This approach may also be used with pMOS devices, where the stressor material 614 comprises germanium or silicon germanium with a germanium concentration greater than that of the second silicon germanium layer 606 in order to enable a larger compressive stress in the pFinFET channel. In some embodiments, the stressor for the pMOS may also comprise up to 8% tin to further increase the compressive stress. Separate stress materials for nMOS and pMOS regions may be achieved using patterning, screen dielectrics, and selective epitaxial depositions that are well established. In some embodiments, the stressor material 614 will be in situ n-doped with, for example, phosphorus and/or arsenic in the nMOS region. In some embodiments, the stressor material 614 will be in situ p-doped with, for example, boron in the pMOS region.

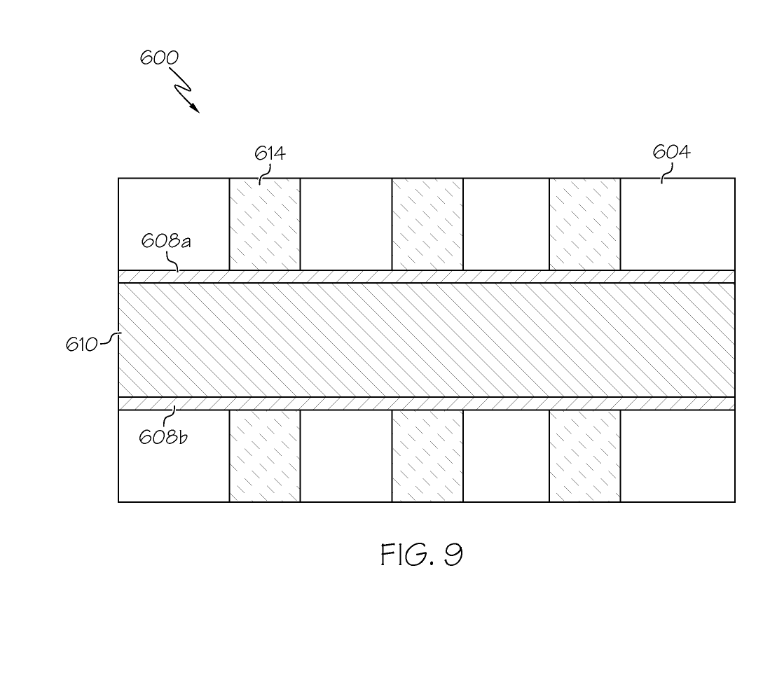

FIG. 9 is a top-down view of a semiconductor structure 600 in accordance with embodiments of the present invention. Semiconductor structure 600 is shown with stressor material 614 atop second SiGe layer 606 (not shown).

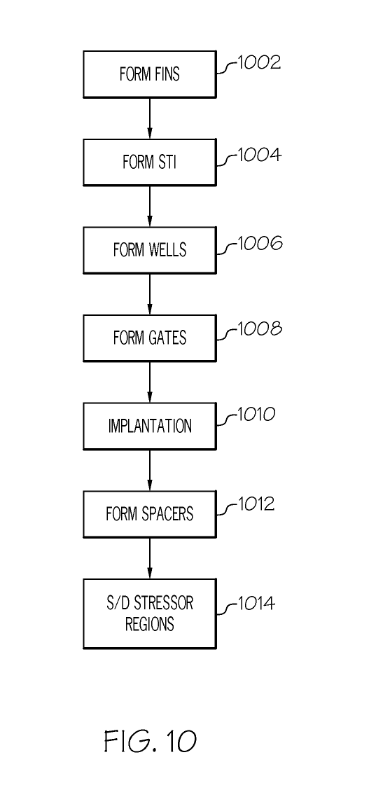

FIG. 10 is a flowchart showing process steps for embodiments of the present invention. At step 1002, fins are formed. This includes depositing the first SiGe layer and the second SiGe layer and forming fins. Fins may be formed through direct patterning using standard photolithographic techniques, self-aligned double patterning techniques such as SIT (sidewall image transfer), or any other suitable process. At step 1004, STI is formed. At 1006, wells are formed. At 1008, gates are formed. At 1010, implantation is performed (adding the dopants to the S/D regions). At 1012, spacers are formed (not shown). At 1014, source/drain (S/D) stressor regions are formed. In some embodiments, the process could include more or fewer steps, and/or the order of the steps may be changed without departing from the scope of the invention. For example, in some embodiments, wells may be formed (1006) prior to forming the STI (1004). In some embodiments, the n and p doped wells may be formed after the first silicon germanium depositions and before the second silicon germanium deposition. Alternatively, wells may be formed (1006) before fins are formed (1002). Alternatively, the STI may be formed (1004) prior to forming fins (1002) and then using a replacement fin technique for the SiGe fin formation (i.e., etch SiGe SRB (first SiGe layer) in exposed fins to desired depth, then replace with the second SiGe layer channel). These modifications are examples, and any suitable combination and order of steps may be performed within the scope of the invention.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Moreover, in particular regard to the various functions performed by the above described components (assemblies, devices, circuits, etc.) the terms used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application. Therefore, it is to be understood that the appended claims are intended to cover all such modifications and changes that fall within the true spirit of the invention.

What is claimed is:

1. A semiconductor structure comprising:
a semiconductor substrate;
a first silicon germanium layer disposed on the semiconductor substrate;
a second silicon germanium layer disposed on the first silicon germanium layer; and
a plurality of shallow trench isolation regions formed in the second silicon germanium layer and partially into the first silicon germanium layer; wherein the first silicon germanium layer has a first germanium concentration, and wherein the second silicon germanium layer has a second germanium concentration, and wherein the second germanium concentration is greater than the first germanium concentration.

2. The semiconductor structure of claim 1, wherein the first germanium concentration ranges from about 40 percent to about 60 percent, and the second germanium concentration ranges from about 90 percent to about 95 percent.

3. The semiconductor structure of claim 1, wherein the first germanium concentration ranges from about 60 percent to about 70 percent, and the second germanium concentration ranges from about 75 percent to about 90 percent.

4. The semiconductor structure of claim 1, wherein the first germanium concentration ranges from about 80 percent to about 85 percent, and the second germanium concentration ranges from about 90 percent to about 95 percent.

5. The semiconductor structure of claim 1, wherein the first silicon germanium layer has a germanium atomic fraction y and second silicon germanium layer has a germanium atomic fraction x such that 0.8≦x≦1 and y≧−3.5x+3.6.

6. A semiconductor structure comprising:
a semiconductor substrate;
a first silicon germanium layer disposed on the semiconductor substrate;
a second silicon germanium layer disposed on the first silicon germanium layer; and
a plurality of shallow trench isolation regions formed in the second silicon germanium layer and partially into the first silicon germanium layer; wherein the first silicon germanium layer has a first germanium concentration, and wherein the second silicon germanium layer has a second germanium concentration, and wherein the second germanium concentration is greater than the first germanium concentration; and
wherein a conduction band offset between the second silicon germanium layer and the first silicon germanium layer ranges from about −0.05 eV to about −0.15 eV, and wherein a valence band offset between the second silicon germanium layer and the first silicon germanium layer ranges from about 0.05 eV to about 0.4 eV.

7. The semiconductor structure of claim 6, further comprising an nMOS region and a pMOS region, and wherein the first silicon germanium layer comprises a p-doped region in the nMOS region of the semiconductor structure and an n-doped region in the pMOS region of the semiconductor structure.

8. The semiconductor structure of claim 7, wherein a source region and a drain region for the pMOS region contains compressively-strained silicon germanium with a germanium concentration higher than that of the second silicon germanium layer.

9. The semiconductor structure of claim 7, wherein a source region and a drain region for the nMOS region contain tensile-strained silicon or silicon germanium with a germanium concentration at least 10% lower than that of the first silicon germanium layer.

10. The semiconductor structure of claim 6, wherein the first silicon germanium layer has a thickness that ranges from about 100 nanometers to about 2000 nanometers.

11. The semiconductor structure of claim 6, wherein the second silicon germanium layer has a thickness that ranges from about 10 nanometers to about 90 nanometers.

12. The semiconductor structure of claim 6, further comprising:
a p-type field effect transistor formed on the second silicon germanium layer; and
an n-type field effect transistor formed on the second silicon germanium layer and disposed adjacent to the p-type field effect transistor.

13. The semiconductor structure of claim 12, wherein the p-type field effect transistor is a fin-type field effect transistor and wherein the n-type field effect transistor is a fin-type field effect transistor.

14. A method of forming a semiconductor structure, comprising:
forming a first silicon germanium layer on a semiconductor substrate, the first silicon germanium layer having a first germanium concentration;
forming a p-doped region in the first silicon germanium layer;
forming an n-doped region in the first silicon germanium layer; and
forming a second silicon germanium layer on the first silicon germanium layer, the second silicon germanium layer having a second germanium concentration that is greater than the first germanium concentration.

15. The method of claim 14, further comprising forming a plurality of shallow trench isolation regions in the second silicon germanium layer and partially into the first silicon germanium layer.

16. The method of claim 14, further comprising forming a plurality of fins in the second silicon germanium layer.

17. The method of claim 16, further comprising forming stressor regions on the plurality of fins.

18. The method of claim 17, wherein forming stressor regions comprises:
depositing a compressively-strained silicon germanium layer on a subset of the plurality of fins that correspond to a PFET device; and
depositing a tensile-strained silicon germanium layer on a subset of the plurality of fins that correspond to an NFET device.

19. The method of claim 18, further comprising:
forming a first set of fin recesses in a plurality of nMOS source and drain regions prior to performing a deposition of strained source drain materials; and
forming a second set of fin recesses in a plurality of pMOS source and drain regions prior to performing a deposition of strained source drain materials;
wherein the first set of fin recesses is at least 5 nanometers deeper than the second set of fin recesses.

20. The method of claim 14, wherein a conduction band offset between the second silicon germanium layer and the first silicon germanium layer ranges from about −0.05 eV to about −0.15 eV, and wherein a valence band offset between the second silicon germanium layer and first silicon germanium layer ranges from about 0.05 eV to about 0.4 eV.
